(19) United States
(12) Patent Application Publication
(10) Pub. No.: US 2017/0044010 A1
(43) Pub. Date: Feb. 16, 2017

(54) SENSOR ELEMENT, METHOD FOR MANUFACTURING SENSOR ELEMENT, DETECTION DEVICE, AND METHOD FOR MANUFACTURING DETECTION DEVICE

(71) Applicant: Mitsubishi Electric Corporation, Chiyoda-ku, Tokyo (JP)

(72) Inventors: Tomoya HIRATA, Chiyoda-ku, Tokyo (JP); Taiki NAKANISHI, Chiyoda-ku, Tokyo (JP); Hiromoto INOUE, Chiyoda-ku, Tokyo (JP); Yoshitatsu KAWAMA, Chiyoda-ku, Tokyo (JP)

(73) Assignee: Mitsubishi Electric Corporation, Chiyoda-ku, Tokyo (JP)

(21) Appl. No.: 15/118,686

(22) PCT Filed: Mar. 31, 2015
(86) PCT No.: PCT/JP2015/060135

§ 371 Date: Aug. 12, 2016

(30) Foreign Application Priority Data
Apr. 2, 2014 (JP) 2014-076039

(51) Int. Cl. B81C 1/00; G01F 1/692; B81B 3/00

(52) U.S. Cl. CPC B81C 1/00674; B81B 3/0075; G01F 1/692; B81C 2201/0161; B81C 2201/053; B81C 2201/0102; B81C 2201/0111; B81B 2201/0264; B81C 2201/0143; B81B 2207/99; B81B 2203/0315

(57) ABSTRACT

There is provided a sensor element including: a semiconductor base member having a first main surface and a second main surface located opposite to the first main surface, and having a cavity structure formed on the second main surface side; and a detection element formed on the first main surface side in a region where the cavity structure is formed, the second main surface of the semiconductor base member including a convexly and concavely shaped portion, and a tip of a convex portion of the convexly and concavely shaped portion having a curved shape.

### TECHNICAL FIELD

The present invention relates to a sensor element used in a semiconductor technology and an MEMS (Micro Electro Mechanical System, hereinafter referred to as “MEMS”) technology, and particularly relates to a sensor element having a cavity structure formed by anisotropic etching from a rear surface of a substrate.

### BACKGROUND ART

In recent years, a microfabrication method using the semiconductor technology and the MEMS technology has been introduced into sensor elements and the sensor elements tend to have a more delicate and complicated structure. Examples of a sensor element having a cavity (thin-film hollow structure) formed by partially removing a base member, among the aforementioned sensor elements, include a pressure sensor, an ultrasonic sensor, a flow rate sensor and the like.

For example, the flow rate sensor has a temperature-dependent resistor formed above a cavity structure. Namely, a detection portion of the flow rate sensor is formed on the cavity structure. Specifically, a heat generator and an intake air temperature detector are formed above the cavity structure, and by using an element structure controlled such that a temperature of the heat generator becomes higher by a certain temperature than a temperature detected by the intake air temperature detector, a voltage corresponding to an amount of heat released to a fluid by the heat generator is defined as an output.

Examples of a method for forming the cavity structure in such a sensor element include a method for performing wet etching treatment by using a mask film having an opening on a region of a semiconductor substrate where a cavity structure is to be formed.

For example, Japanese Patent Laying-Open No. 11-295127 describes a side flow rate detection element having base member protection films formed on a rear side surface and a front side surface of a base member. Japanese Patent Laying-Open No. 11-295127 describes that it is possible to suppress shape disorder of a diaphragm portion having a cavity structure caused by a pinhole or a pit formed in a surface opposite to a surface subjected to etching.

Japanese Patent Laying-Open No. 2013-160706 describes a flow rate detection device in which a cavity structure is provided directly below a wafer surface such as a wiring and a circuit by wet etching with a KOH (potassium hydroxide) chemical solution or a TMAH (tetramethylammonium hydroxide, hereinafter referred to as “TMAH”) chemical solution, with a rear surface protection film, in addition to a thermally oxidized film, being formed on a rear surface of a silicon wafer.

In addition, Japanese Patent Laying-Open No. 2012-98072 describes a flow rate detection device having textured convex portions and concave portions formed on a surface facing an incorporation portion where a sensor element is arranged. Japanese Patent Laying-Open No. 2012-98072 describes that since the convex portions and concave portions are formed, the throwing power of an adhesive for bonding the sensor element and a support member can be enhanced and the seepage of a bottom flow inhibitor can be inhibited.

In addition, Japanese Patent National Publication No. 2013-518425 describes a method for manufacturing a photovoltaic cell, including the step of performing anisotropic etching treatment and thereafter isotropic etching treatment to a crystalline silicon substrate.

### CITATION LIST

### Patent Document

PTD 1: Japanese Patent Laying-Open No. 11-295127

PTD 2: Japanese Patent Laying-Open No. 2013-160706

PTD 3: Japanese Patent Laying-Open No. 2012-98072

PTD 4: Japanese Patent National Publication No. 2013-518425

### SUMMARY OF INVENTION

### Technical Problem

However, in a conventional sensor element, a foreign substance such as silicon chips may produce a linear scratch or an indentation in a protection film. In this case, in a subsequent wet etching step, entry of an etchant from the scratch or the indentation may occur, and thus, a rectangular etching trace (pit) may be produced, or a base member may be subjected to excessive etching and a dimension of a hollow portion of a cavity may become larger than a design dimension, which may lead to variations in shape of the cavity. As a result, when the sensor element is pressed such as when the sensor element is mounted on a support member, local stress concentration may occur, which may lead to breakage. In addition, when the sensor element is a pressure sensor or the like, the reliability of the sensor element may decrease due to being pressed during use.

In addition, the textured convex portions and concave portions described in Japanese Patent Laying-Open No. 2012-98072 and Japanese Patent National Publication No. 2013-518425 are formed by deposition of a (111) plane having a low etching rate because a (100) plane and the (111) plane of silicon have different etching rates. Because of their sharp convex portions, the aforementioned convex portions and concave portions are easily chipped and a pit is easily formed, disadvantageously.

In addition, even in the manufacturing method described in Japanese Patent National Publication No. 2013-518425, the textured convex portions and concave portions have a portion where the (111) plane is exposed. Therefore, when a semiconductor substrate including the aforementioned convex portions and concave portions is pressed with a foreign substance or the like being stuck in the convex portions and concave portions, the semiconductor substrate is easily broken along the (111) plane. Thus, a sensor element including the semiconductor substrate having the aforementioned convex portions and concave portions is insufficient in pressing resistance, disadvantageously.

The present invention has been made to solve the aforementioned problem. A main object of the present invention is to provide a sensor element, a method for manufacturing the sensor element, a detection device, and a method for manufacturing the detection device, which make it possible to suppress formation of a pit or variations in shape of a cavity, and which achieve a high resistance during pressing.

### Solution to Problem

A sensor element according to the present invention includes: a semiconductor base member having a first main surface and a second main surface located opposite to the first main surface, and having a cavity structure formed on the second main surface side; and a detection element formed on the first main surface side in a region where the cavity structure is formed, the second main surface of the semiconductor base member including a convexly and concavely shaped portion, and a tip of a convex portion of the convexly and concavely shaped portion having a curved shape.

A method for manufacturing a sensor element according to the present invention includes the steps of: preparing a semiconductor substrate having a first main surface and a second main surface located opposite to the first main surface; forming a convexly and concavely shaped portion on the second main surface of the semiconductor substrate; forming a protection film on the convexly and concavely shaped portion; forming a cavity structure by forming an opening pattern in the protection film and etching the semiconductor substrate exposed in the opening pattern by using the protection film as a mask; and forming a detection element on the first main surface side in a region where the cavity structure is formed. In the step of forming the convexly and concavely shaped portion, the convexly and concavely shaped portion is formed such that a tip of a convex portion of the convexly and concavely shaped portion has a curved shape.

### Advantageous Effects of Invention

According to the present invention, there can be provided a sensor element, a method for manufacturing the sensor element, a detection device, and a method for manufacturing the detection device, which make it possible to suppress formation of a pit or variations in shape of a cavity, and which achieve a high resistance during pressing.

### BRIEF DESCRIPTION OF DRAWINGS

FIG. 1 is a top view for describing a sensor element according to a first embodiment.

FIG. 2 is a cross-sectional view when viewed from line II-II in FIG. 1.

FIG. 3 is a cross-sectional view for describing a convexly and concavely shaped portion of the sensor element according to the first embodiment.

FIG. 4 is a flowchart of a method for manufacturing the sensor element according to the first embodiment.

FIG. 5 is a cross-sectional view for describing the method for manufacturing the sensor element according to the first embodiment.

FIG. 6 is a cross-sectional view for describing the method for manufacturing the sensor element according to the first embodiment.

FIG. 7 is a cross-sectional view for describing the method for manufacturing the sensor element according to the first embodiment.

FIG. 8 is a cross-sectional view for describing the method for manufacturing the sensor element according to the first embodiment.

FIG. 9 is a cross-sectional view for describing the method for manufacturing the sensor element according to the first embodiment.

FIG. 10 is a cross-sectional view for describing the method for manufacturing the sensor element according to the first embodiment.

FIG. 11 is a plan view when viewed from arrow XI in FIG. 10.

FIG. 12 is a cross-sectional view for describing the method for manufacturing the sensor element according to the first embodiment.

FIG. 13 is a cross-sectional view for describing a function and effect of the sensor element according to the first embodiment.

FIG. 14 is a cross-sectional view for describing the function and effect of the sensor element according to the first embodiment.

FIG. 15 is a top view for describing a detection device according to a second embodiment.

FIG. 16 is a cross-sectional view when viewed from line XVI-XVI in FIG. 15.

FIG. 17 is a flowchart of a modification of the method for manufacturing the sensor element according to the first embodiment.

FIG. 18 is a partial cross-sectional view of a second main surface of a semiconductor substrate after the step of forming a convexly and concavely shaped portion and before the step of removing a cracked layer in a method for manufacturing a sensor element according to a third embodiment.

FIG. 19 is a flowchart of the method for manufacturing the sensor element according to the third embodiment.

FIG. 20 is a flowchart of a modification of the method for manufacturing the sensor element according to the third embodiment.

### DESCRIPTION OF EMBODIMENTS

Embodiments of the present invention will be described hereinafter with reference to the drawings. In the following drawings, the same or corresponding portions are denoted by the same reference numerals and description thereof will not be repeated.

### First Embodiment

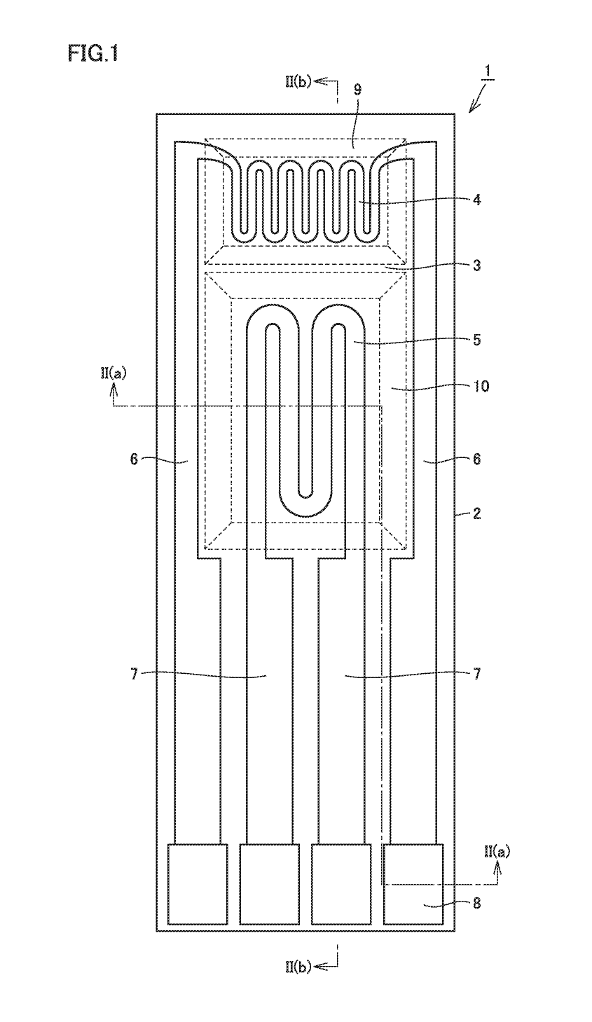

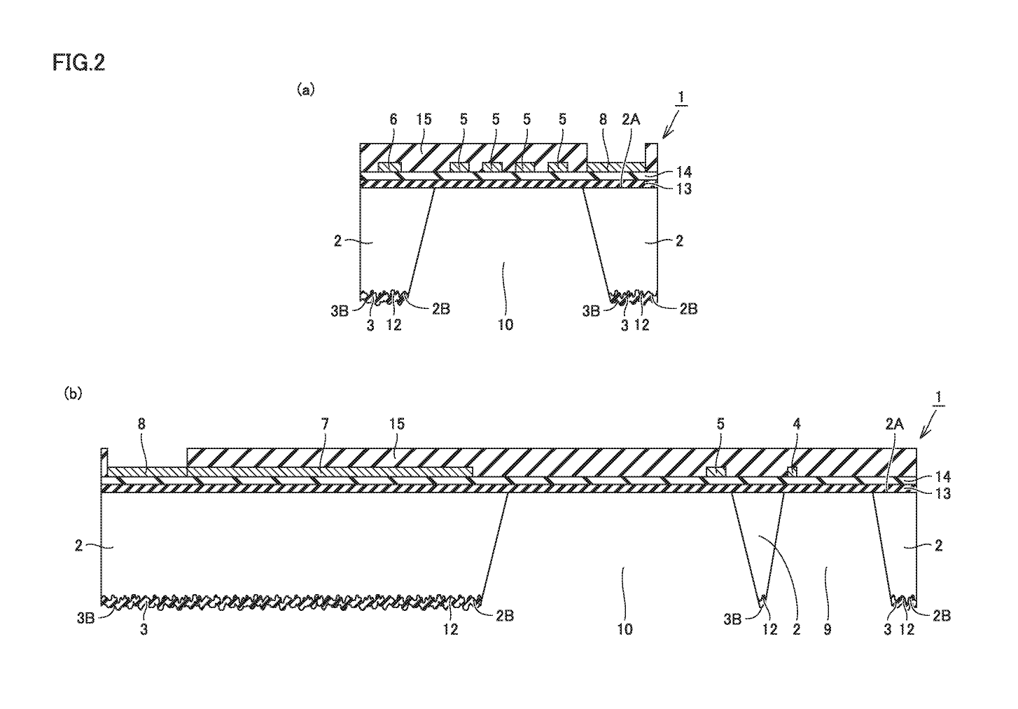

A sensor element 1 according to a first embodiment will be described with reference to FIGS. 1 to 3. Sensor element 1 according to the first embodiment is, for example, a flow rate detection element used in a flow rate detection device. Sensor element 1 includes a semiconductor base member 2 having a first main surface 2A and a second main surface 2B located opposite to first main surface 2A. First main surface 2A is a surface which faces a path of a fluid to be detected by sensor element 1 and which is in contact with the fluid.

Semiconductor base member 2 has cavity structures 9 and 10 formed on the second main surface 2B side. Cavity structures 9 and 10 are provided such that cavity structures 9 and 10 extend from second main surface 2B to first main surface 2A and semiconductor base member 2 has a so-called reverse tapered shape. In other words, in semiconductor base member 2, first main surface 2A is formed over a wider region than second main surface 2B. Although semiconductor base member 2 may have an arbitrary thickness, the thickness of semiconductor base member 2 is, for example, 0.5 mm. Although a material forming semiconductor base member 2 can be an arbitrary semiconductor material, the material forming semiconductor base member 2 is, for example, silicon (Si).

A convexly and concavely shaped portion 12 is formed over entire second main surface 2B of semiconductor base member 2, and a lower protection film 3 is formed on the entire region of convexly and concavely shaped portion 12. Since convexly and concavely shaped portion 12 is formed, second main surface 2B has a prescribed surface roughness. Convexly and concavely shaped portion 12 and lower protection film 3 are formed such that a ten-point average roughness Rz (former JIS2001) of second main surface 2B is greater than a film thickness of lower protection film 3. Ten-point average roughness Rz of first main surface 2A is smaller than that of the second main surface and first main surface 2A is, for example, a mirror surface.

Ten-point average roughness Rz of second main surface 2B of semiconductor base member 2 is not smaller than 0.05 μm, and preferably not smaller than 1.00 μm. In addition, an arithmetic average roughness Ra of second main surface 2B is, for example, not smaller than 0.01 μm, and preferably not smaller than 0.25 μm. From the perspective of suppressing formation of an etching pit, greater ten-point average roughness Rz of second main surface 2B is more preferable. Generally, when this roughness Rz becomes too great, it is concerned that the strength of semiconductor base member 2 may decrease, which may cause breakage and the like. Therefore, a value larger than an outer diameter of a foreign substance having a high frequency of occurrence may be set as an upper limit value of roughness Rz. For example, when a frequency of occurrence of a foreign substance having an outer diameter of approximately 5.00 μm or smaller is high, the upper limit value of roughness Rz may be 5.00 μm. By limiting roughness Rz within such a numerical range, the decrease in strength of semiconductor base member 2 can be suppressed and the formation of the etching pit can be sufficiently suppressed.

A tip of a convex portion of convexly and concavely shaped portion 12 is rounded. From a different perspective, convexly and concavely shaped portion 12 does not have a pyramid shape. Convexly and concavely shaped portion 12 does not have, for example, a quadrangular pyramid shape formed such that a plurality of surfaces formed to radially extend from a vertex intersect with one another in semiconductor base member 2. The convex end of convexly and concavely shaped portion 12 is, for example, formed hemispherically.

The film thickness of lower protection film 3 is, for example, not smaller than 0.25 μm and not greater than 1.50 μm, and preferably not smaller than 0.50 μm and not greater than 1.00 μm. A material forming lower protection film 3 is, for example, silicon dioxide (SiO₂). In this case, lower protection film 3 can be formed, for example, by thermally oxidizing, as Si, the material forming semiconductor base member 2. Lower protection film 3 does not need to be formed to have a uniform film thickness on convexly and concavely shaped portion 12. As long as ten-point average roughness Rz of second main surface 2B and the film thickness of lower protection film 3 satisfy the aforementioned relational equation, the film thickness of lower protection film 3 may have variations.

On the first main surface 2A side of sensor element 1, an upper protection film 13 and a support film 14 are formed to cover openings of cavity structures 9 and 10 from first main surface 2A. Although a material forming upper protection film 13 can be an arbitrary material having an electrical insulation property, the material forming upper protection film 13 is, for example, SiO₂. Upper protection film 13 can be formed, for example, simultaneously with lower protection film 3. Although a material forming support film 14 can be an arbitrary material that has an electrical insulation property and can support detection elements 4 and 5, the material forming support film 14 is, for example, silicon nitride (SiN), SiO₂ or the like.

In sensor element 1, detection elements 4 and 5 are formed on the first main surface 2A side in the regions where cavity structures 9 and 10 are formed. Detection element 4 is, for example, an intake air temperature detector 4, and detection element 5 is, for example, a heat generator 5.

Intake air temperature detector 4 is formed on upper protection film 13 formed in the region where cavity structure 9 is formed, and heat generator 5 is formed on upper protection film 13 formed in the region where cavity structure 10 is formed. Intake air temperature detector 4 and heat generator 5 are electrically connected to electrode pads 8 by wiring patterns 6 and 7, respectively. A plurality of electrode pads 8 are formed, and electrode pad 8 electrically connected to intake air temperature detector 4 by wiring pattern 6 and electrode pad 8 electrically connected to heat generator 5 by wiring pattern 7 are electrically insulated from each other. Wiring patterns 6 and 7 and electrode pads 8 are formed on support film 14.

Intake air temperature detector 4 and heat generator 5 are formed to meander on support film 14. As a result, a contact area between intake air temperature detector 4 and heat generator 5 and the fluid to be detected can be increased.

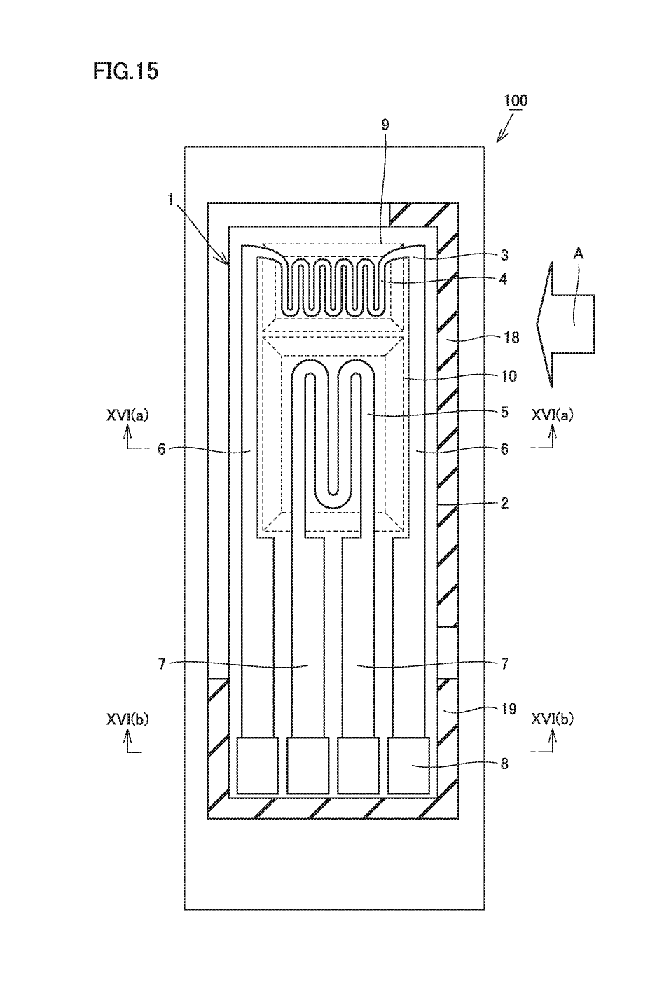

A positional relation between intake air temperature detector 4 and heat generator 5 can be an arbitrary positional relation. However, intake air temperature detector 4 and heat generator 5 may be arranged in parallel with a flowing direction A (see FIG. 15) of the fluid to be detected, when sensor element 1 is configured, for example, as a flow rate detection device. Alternatively, intake air temperature detector 4 and heat generator 5 may be arranged serially with respect to flowing direction A of the fluid.

As long as a sufficient contact area between intake air temperature detector 4 and the fluid to be detected is obtained, a planar dimension of intake air temperature detector 4 on first main surface 2A (hereinafter simply referred to as “planar dimension”) can be an arbitrary dimension. However, a dimension in a direction parallel to flowing direction A of the fluid to be detected is not smaller than 0.3 mm and not larger than 0.8 mm, and a dimension in a direction crossing direction A is not smaller than 0.2 mm and not larger than 0.6 mm, for example.

As long as heat generator 5 can provide a sufficient amount of heat to the fluid to be detected, a planar dimension of heat generator 5 can be an arbitrary dimension. However, a dimension in the direction parallel to flowing direction A of the fluid to be detected is not smaller than 0.3 mm and not larger than 0.8 mm, and a dimension in the direction crossing direction A is not smaller than 0.8 mm and not larger than 1.8 mm, for example. Intake air temperature detector 4 and heat generator 5 are provided such that the planar dimension of intake air temperature detector 4 is smaller than the planar dimension of heat generator 5, for example. Intake air temperature detector 4 and heat generator 5 are provided such that the planar dimension of intake air temperature detector 4 is smaller than the planar dimension of heat generator 5, for example.

Cavity structure 9 is formed such that a dimension of cavity structure 9 is larger than the planar dimension of intake air temperature detector 4 on first main surface 2A, and is provided, for example, to be larger by not smaller than 0.7 mm than intake air temperature detector 4 both in the direction parallel to flowing direction A of the fluid to be detected and in the direction crossing direction A.

In addition, cavity structure 10 is formed such that a dimension of cavity structure 10 is larger than the planar dimension of heat generator 5 on first main surface 2A, and is provided, for example, to be larger by not smaller than 0.7 mm than heat generator 5 both in the direction parallel to flowing direction A of the fluid to be detected and in the direction crossing direction A.

Although each of intake air temperature detector 4 and heat generator 5 may be formed as an arbitrary structure by using an arbitrary constituent material, each of intake air temperature detector 4 and heat generator 5 may be formed, for example, as a heat sensitive resistor (temperature measuring resistor) formed of a thin film of a metal such as platinum (Pt). A film thickness of each of intake air temperature detector 4 and heat generator 5 is, for example, not smaller than 100 nm and not greater than 500 nm.

In sensor element 1, a surface protection film 15 is formed on upper protection film 13 and support film 14 to cover intake air temperature detector 4, heat generator 5, and wiring patterns 6 and 7. Although a material forming surface protection film 15 can be an arbitrary material having an electrical insulation property, the material forming surface protection film 15 can, for example, be SiN or SiO₂.

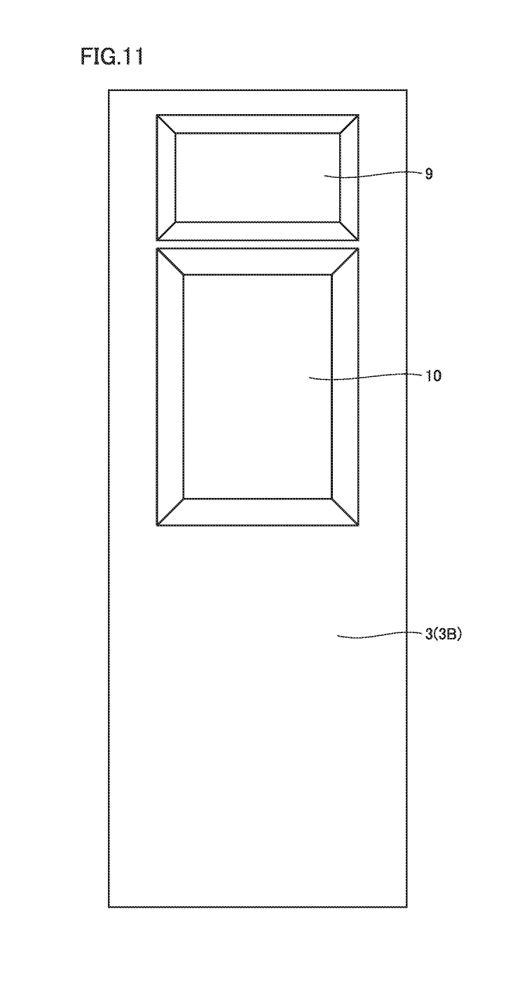

Next, a method for manufacturing sensor element 1 according to the first embodiment will be described with reference to FIGS. 4 to 12. The method for manufacturing sensor element 1 includes: the step (S10) of preparing semiconductor base member 2 having first main surface 2A and second main surface 2B located opposite to first main surface 2A; the step (S20) of forming convexly and concavely shaped portion 12 on second main surface 2B of semiconductor base member 2; the step (S30) of forming the protection film (lower protection film 3) on convexly and concavely shaped portion 12; the step (S40) of forming detection elements 4 and 5 on the first main surface 2A side in the regions where cavity structures 9 and 10 are to be formed; and the step (S50) of forming cavity structures 9 and 10 by forming an opening pattern in the protection film (lower protection film 3) and etching semiconductor base member 2 exposed in the opening pattern by using lower protection film 3 as a mask.

First, referring to FIG. 5, semiconductor base member 2 having first main surface 2A and second main surface 2B located opposite to first main surface 2A is prepared (step (S10)). Semiconductor base member 2 may be prepared as a substrate made of an arbitrary semiconductor material and having at least mirror-polished first main surface 2A. However, semiconductor base member 2 may be, for example, a silicon substrate having mirror-polished first main surface 2A and second main surface 2B. A wafer thickness of semiconductor base member 2 is, for example, 625 μm.

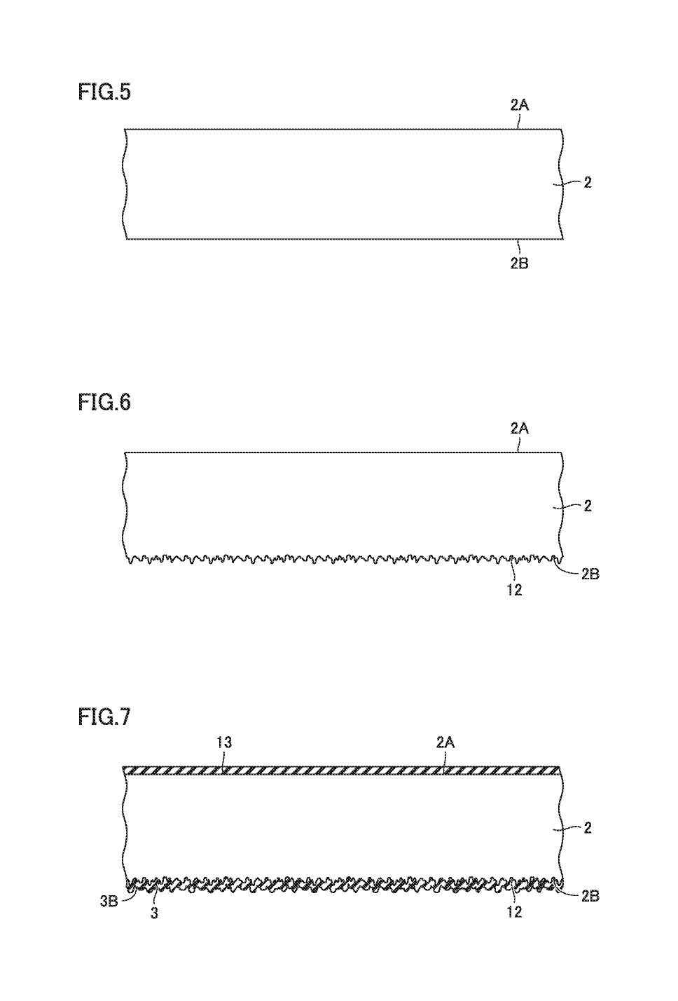

Next, referring to FIG. 6, convexly and concavely shaped portion 12 is formed on second main surface 2B of semiconductor base member 2 (step (S20)). As long as convexly and concavely shaped portion 12 can be formed such that the convex end of convexly and concavely shaped portion 12 is rounded and ten-point average roughness Rz of second main surface 2B is greater than the film thickness of lower protection film 3 to be formed in the subsequent step (S30), an arbitrary method can be adopted as a method for forming convexly and concavely shaped portion 12 on second main surface 2B. Convexly and concavely shaped portion 12 can be formed, for example, by grinding second main surface 2B to make second main surface 2B rough. Grinding can be performed, for example, by using a grindstone having a grain size of not smaller than 100 and not larger than 2000. As a result, ten-point average roughness Rz of convexly and concavely shaped portion 12 can be not smaller than 0.06 μm and not greater than 5.0 μm.

Next, lower protection film 3 is formed on convexly and concavely shaped portion 12 (step (S30)). Specifically, referring to FIG. 7, lower protection film 3 is formed on entire second main surface 2B. An arbitrary film formation method such as sputtering and CVD (chemical vapor deposition) can be adopted as a method for forming lower protection film 3. However, lower protection film 3 can be formed as a thermally oxidized film (SiO₂), for example, by thermally oxidizing semiconductor base member 2 made of Si. Specifically, for example, by performing heat treatment at a treatment temperature of not lower than 800° C. and not higher than 1100° C. for a prescribed time period in an oxygen-containing atmosphere, thermally oxidized films having a film thickness of not greater than 1 μm can be simultaneously formed on first main surface 2A and second main surface 2B of semiconductor base member 2. At this time, the thermally oxidized film formed on first main surface 2A corresponds to upper protection film 13, and the thermally oxidized film formed on second main surface 2B corresponds to lower protection film 3. Namely, upper protection film 13 and lower protection film 3 can be simultaneously formed by thermally oxidizing semiconductor base member 2.

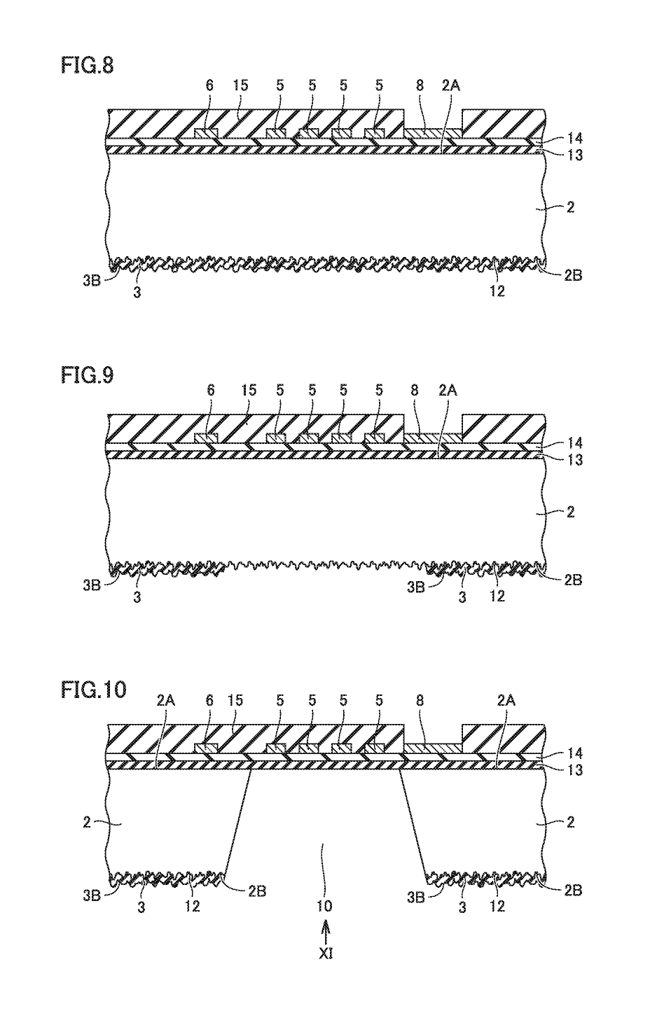

Next, referring to FIG. 8, detection elements 4 and 5 are formed on the first main surface 2A side in the regions where cavity structures 9 and 10 are to be formed (step (S40)). Specifically, support film 14, intake air temperature detector 4, heat generator 5, wiring patterns 6 and 7, electrode pad 8, and surface protection film 15 are formed on upper protection film 13 formed on first main surface 2A.

A reactive sputtering method, a CVD method or the like can, for example, be adopted as a method for forming support film 14. Although film formation conditions for reactive sputtering can be arbitrarily selected in accordance with the configuration of support film 14, support film 14 made of SiN can be formed, for example, by performing sputtering in a nitrogen gas atmosphere using Si as a target material. In this case, the film formation speed can be increased as compared with the case of using SiN as a target material. In the case of film formation by the CVD method, support film 14 can be formed by using ordinary pressure CVD, reduced pressure CVD, plasma CVD or the like and setting a film formation temperature to be not lower than 300° C. and not higher than 400° C. When support film 14 is, for example, a nitride film made of SiN or the like, an ammonia gas is, for example, used as a raw material gas, in addition to monosilane, disilane and the like. When support film 14 is, for example, an oxide film made of SiO₂ or the like, nitrous oxide, an oxygen gas or the like is, for example, used as a raw material gas, in addition to monosilane, disilane and the like. A TEOS-CVD method can be adopted as a method for providing support film 14 made of SiO₂. Since the CVD method is superior in step coverage and stress controllability to the sputtering method, the CVD method is used for formation of support film 14 and surface protection film 15, and thereby, a dense and thin film can be formed.

Each of intake air temperature detector 4, heat generator 5, wiring patterns 6 and 7, and electrode pad 8 may be formed by using an arbitrary method. For example, film formation is performed by a vapor deposition method or a sputtering method, and patterning is performed by a dry etching method or a wet etching method by using a photomechanically formed mask pattern. In this way, a prescribed current path pattern is formed in sensor element 1.

Next, referring to FIG. 9, the opening pattern is formed in lower protection film 3 in the regions where cavity structures 9 and 10 are to be formed. The region where cavity structure 9 is to be formed is a region where intake air temperature detector 4 is to be formed, and the region where cavity structure 10 is to be formed is a region where heat generator 5 is to be formed. Although an arbitrary method can be adopted as a method for forming the opening pattern in lower protection film 3, a photolithography method or a dry etching method can, for example, be adopted. Specifically, lower protection film 3 having the opening pattern in the regions where cavity structures 9 and 10 are to be formed may be formed by forming a mask pattern (not shown) having the opening pattern by the photolithography method on lower protection film 3 in the regions where cavity structures 9 and 10 are to be formed, and dry etching lower protection film 3 by using this mask pattern.

Next, referring to FIG. 10, cavity structures 9 and 10 are formed by partially etching semiconductor base member 2 from the second main surface 2B side by using lower protection film 3 as a mask (step (S50)). Lower protection film 3 formed in the previous step (S40) has the opening pattern in the regions where cavity structures 9 and 10 are to be formed. Therefore, by etching semiconductor base member 2 by using this as a mask, cavity structures 9 and 10 can be formed in the regions where cavity structures 9 and 10 are to be formed, respectively. Although an arbitrary method can be adopted as a method for forming cavity structures 9 and 10, a wet etching method with TMAH, KOH or the like is, for example, used. Specifically, cavity structures 9 and 10 extending from second main surface 2B to first main surface 2A can be formed by immersing semiconductor base member 2 in a bath containing heated TMAH, KOH or the like. Upper protection film 13 is exposed in cavity structures 9 and 10, and intake air temperature detector 4 and heat generator 5 are formed on this upper protection film 13. From the different perspective, cavity structures 9 and 10 are closed by upper protection film 13 on the first main surface 2A side. In this way, a plurality of sensor elements 1 are formed on semiconductor base member 2.

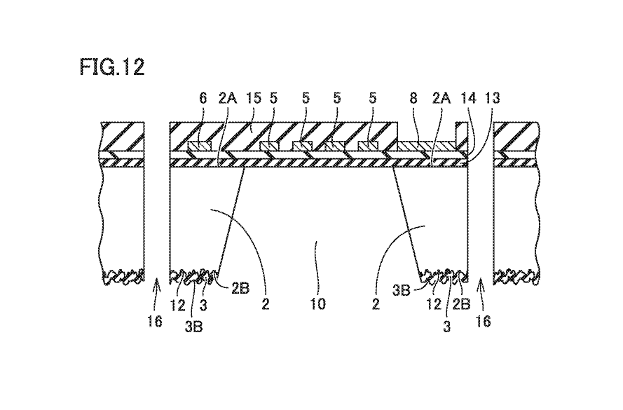

Next, referring to FIG. 12, the plurality of sensor elements 1 formed on semiconductor base member 2 are divided. Although an arbitrary method can be adopted as a method for dividing sensor elements 1, a blade dicing method can, for example, be used. A dicing line 16 is provided, for example, in a region where cavity structures 9 and 10 are not formed. As described above, sensor element 1 according to the first embodiment can be obtained.

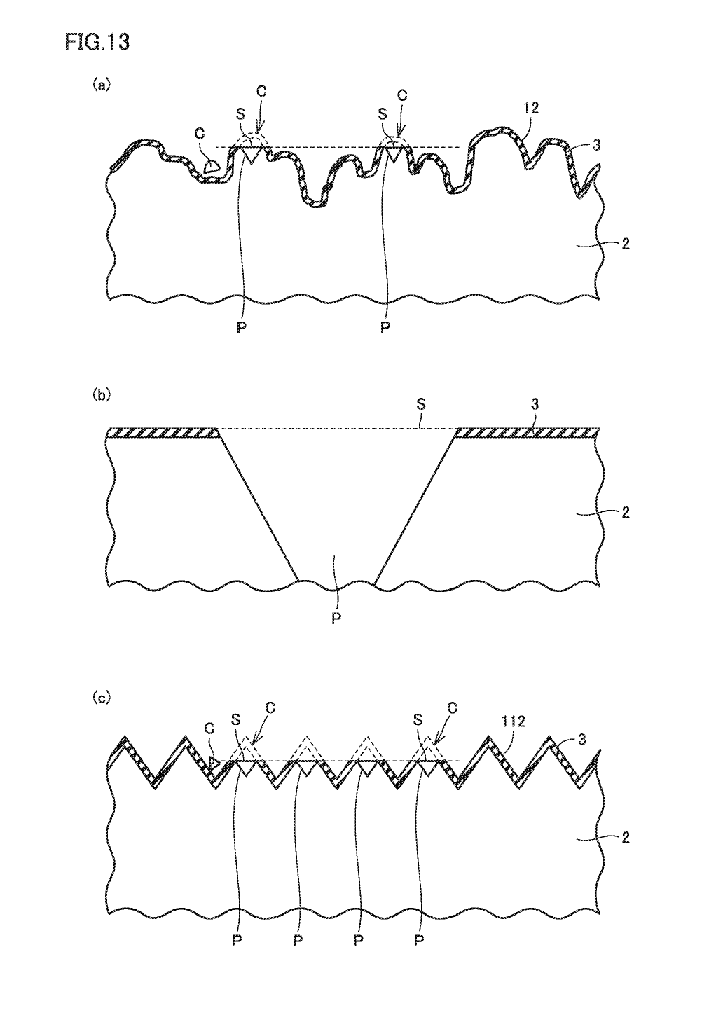

Next, a function and effect of sensor element 1 according to the first embodiment will be described. Second main surface 2B of semiconductor base member 2 in sensor element 1 includes convexly and concavely shaped portion 12, and the tip of the convex portion of convexly and concavely shaped portion 12 has a curved shape. As a result, referring to FIGS. 13(a) and 13(b), production of a linearly extending scratch S in lower protection film 3 can be suppressed as compared with a sensor element that does not have convexly and concavely shaped portion 12.

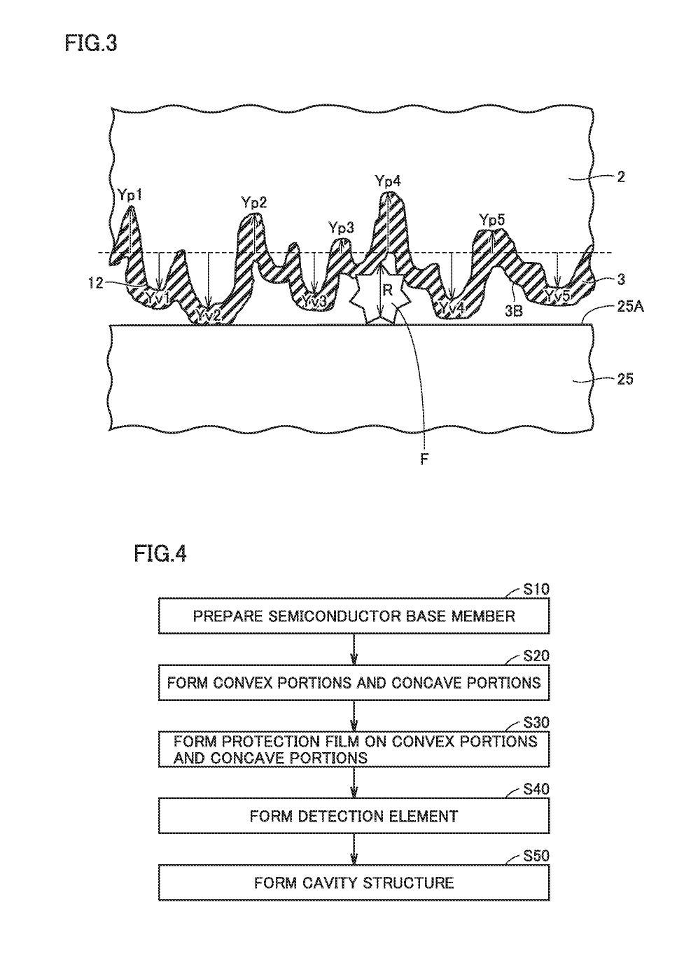

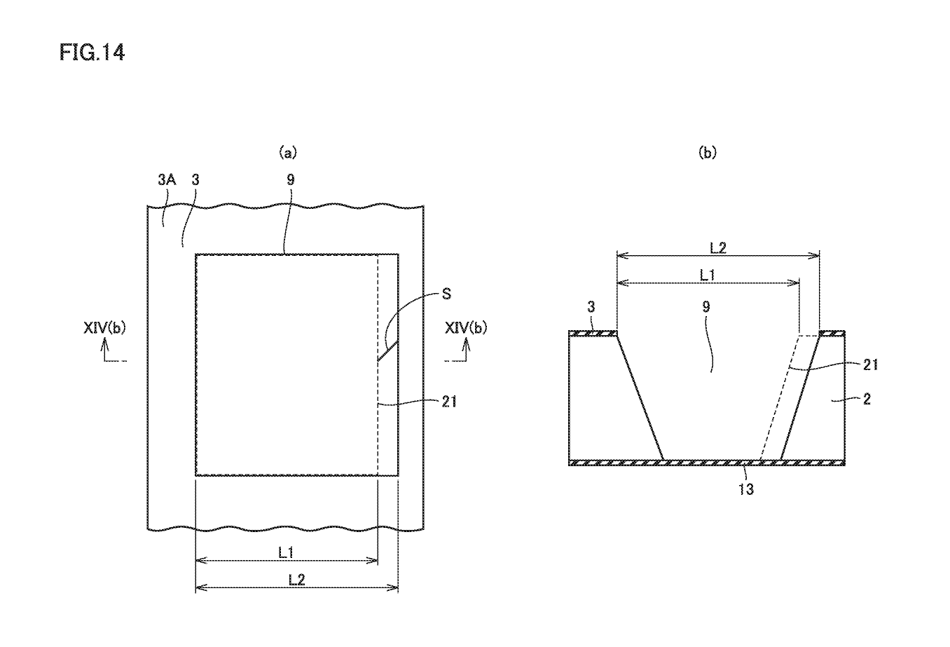

Specifically, second main surface 2B located opposite to detection elements 4 and 5 in sensor element 1 often comes into contact with a stage or the like of various kinds of manufacturing devices in the process of manufacturing sensor element 1. At this time, in a conventional sensor element that does not have convexly and concavely shaped portion 12 as shown in FIG. 13(b), linear scratch S may be formed in lower protection film 3 (see FIG. 14(a)) when the semiconductor substrate is handled with a foreign substance F (see FIG. 3) of a size equal to or greater than the film thickness of the protection film being interposed between the stage and second main surface 2B. Linear scratch S thus formed in lower protection film 3 before the step (S50) becomes an etchant entry path in the step (S50), and thus, a large pit P is formed in the region of lower protection film 3 where scratch S is formed. Referring to FIG. 14(b), particularly when scratch S is formed on a region adjacent to the regions where cavity structures 9 and 10 are to be formed, the dimension of cavity structures 9 and 10 becomes larger than a design dimension thereof and the shape of cavity structures 9 and 10 deviates from a design shape 21 thereof. For example, referring to FIG. 14(a), when scratch S is formed on a region adjacent to a region 17 where cavity structure 9 is to be formed, cavity structure 9 may be formed to reach a position where a distance to region 17 is the longest in scratch S. Thus, when, assuming that cavity structure 9 has a rectangular shape and a design dimension of a side is expressed by L1, for example, scratch S is formed to be adjacent to another side crossing the aforementioned side and scratch S is formed to become longer by a distance L2−L1 in a direction along an extending direction of the aforementioned side, a length of the aforementioned side of cavity structure 9 is expressed by L2 longer than L1 by distance L2−L1. As a result, the conventional sensor element that does not have convexly and concavely shaped portion 12 becomes vulnerable to pressing, and when this conventional sensor element is mounted on a support member, local stress concentration may occur, which may lead to breakage.

In contrast, in sensor element 1 according to the first embodiment, convexly and concavely shaped portion 12 is formed on second main surface 2B, and thus, scratch S can be split into small pieces as compared with the above-described conventional sensor element that does not have convexly and concavely shaped portion 12. As a result, a size of pit P formed due to entry of the etchant from each scratch S can be reduced, and even if scratch S is formed in the region adjacent to the regions where cavity structures 9 and 10 are to be formed, shape disorder of cavity structures 9 and 10 can be significantly reduced. As a result, even when sensor element 1 is pressed, stress concentration is relaxed and breakage is less likely to occur.

Furthermore, in a conventional sensor element in which the convexly and concavely shaped portion is formed as a pyramid shape having a center as shown in FIG. 13(c), scratch S can be split into small pieces and an increase in size of pit P can be suppressed as compared with the above-described conventional sensor element shown in FIG. 13(b). However, the tip of the convex portion of the convexly and concavely shaped portion is easily chipped when second main surface 2B comes into contact with the stage or the like of various kinds of manufacturing devices in the manufacturing process, and such chipped tip piece of the convex portion may produce scratch S in lower protection film 3 as a new foreign substance. As a result, it is difficult to sufficiently reduce scratch S produced in lower protection film 3 and sufficiently suppress deformation of cavity structures 9 and 10, and thus, this conventional sensor element may be vulnerable to pressing similarly to the above-described conventional sensor element.

In contrast, in sensor element 1 according to the first embodiment, the tip of the convex portion of convexly and concavely shaped portion 12 is formed into a curved shape, and thus, chipping of the tip of the convex portion can be suppressed and scratch S produced in lower protection film 3 can be sufficiently reduced. As a result, deformation of cavity structures 9 and 10 of sensor element 1 can be sufficiently suppressed, and even during pressing, stress concentration is relaxed and breakage is less likely to occur.

In addition, as shown in FIG. 13(a), in sensor element 1 according to the first embodiment, ten-point average roughness Rz of convexly and concavely shaped portion 12 is equal to or greater than the film thickness of lower protection film 3. As a result, convexly and concavely shaped portion 12 is not completely flattened by lower protection film 3, and a lower surface 3B of lower protection film 3 has a convex and concave shape that is similar to some extent to the convex and concave shape of second main surface 2B having convexly and concavely shaped portion 12.

Therefore, even when foreign substance F having an outer diameter R (see FIG. 3) approximately equal to or smaller than a size corresponding to a sum of the film thickness of lower protection film 3 and ten-point average roughness Rz of convexly and concavely shaped portion 12 is interposed between second main surface 2B and the stage or the like of various kinds of manufacturing devices in the manufacturing process, production of linearly extending scratch S passing through lower protection film 3 can be suppressed by relative movement or the like of foreign substance F and sensor element 1, because lower surface 3B and second main surface 2B have the convex portions and concave portions caused by ten-point average roughness Rz described above. As a result, in sensor element 1, wide-ranging formation of scratch S in lower protection film 3 by foreign substance F as in the conventional sensor element is suppressed.

In accordance with the method for manufacturing sensor element 1 according to the first embodiment, in the step of forming convexly and concavely shaped portion 12 on second main surface 2B of semiconductor base member 2, convexly and concavely shaped portion 12 is formed such that the tip of the convex portion of convexly and concavely shaped portion 12 has a curved shape. Therefore, as described above, production of linearly extending scratch S in lower protection film 3 can be suppressed, and thus, shape disorder of cavity structures 9 and 10 can be significantly reduced. As a result, even when obtained sensor element 1 is pressed, stress concentration is relaxed and breakage is less likely to occur.

In addition, in the step of forming convexly and concavely shaped portion 12 and the step of forming lower protection film 3, convexly and concavely shaped portion 12 and lower protection film 3 are formed such that the ten-point average roughness of convexly and concavely shaped portion 12 is equal to or greater than the film thickness of the above-described protection film. Therefore, as described above, when sensor element 1 is fixed to the support member and the flow rate detection device is assembled, a contact area between sensor element 1 and an adhesive for connecting and fixing sensor element 1 and the support member can be increased, and the anchor effect of the adhesive can be obtained. Therefore, adhesion between sensor element 1 and the support member can be enhanced.

In addition, in the step (S20) of forming convexly and concavely shaped portion 12, convexly and concavely shaped portion 12 is formed by grinding. Therefore, for example, by changing the grain size of abrasive grains of the grinding stone in accordance with the size of the scratch to be suppressed, deformation of cavity structures 9 and 10 of sensor element 1 can be effectively suppressed. Specifically, by using a grinding stone of a large grain size, ten-point average roughness Rz of convexly and concavely shaped portion 12 can be increased, and a distance of scratch S extending on lower protection film 3 formed on convexly and concavely shaped portion 12 and having a film thickness smaller than this ten-point average roughness Rz can be suppressed.

In addition, desired convexly and concavely shaped portion 12 can be formed only by lapping second main surface 2B of semiconductor base member 2. Therefore, the texturing step and the mirror finishing step can be reduced. Furthermore, an amount of used abrasive (abrasive grains) can be reduced and an amount of used abrasive grains having a high environmental impact can be reduced. As a result, in accordance with the method for manufacturing sensor element 1 according to the first embodiment, the manufacturing cost can be reduced as compared with a method for manufacturing the conventional sensor element.

In addition, the step (S40) of forming detection elements 4 and 5 is performed after the step (S20) of forming convexly and concavely shaped portion 12. However, the tip of the convex portion of convexly and concavely shaped portion 12 is formed into a curved shape in the step (S20), and the step (S30) of forming lower protection film 3 is provided between the step (S20) and the step (S40). Therefore, chipping of the tip of the convex portion of convexly and concavely shaped portion 12 and production of scratch S in lower protection film 3 before the step (S50) of forming cavity structures 9 and 10 can be sufficiently suppressed.

In addition, upper protection film 13 is formed simultaneously with lower protection film 3 in the step (S30). Therefore, upper protection film 13 is configured as a part of the support film of sensor element 1, and thus, the step of forming support film 14 can be shortened.

In the method for manufacturing sensor element 1 according to the first embodiment, convexly and concavely shaped portion 12 is formed by grinding second main surface 2B to make second main surface 2B rough (lapping second main surface 2B) by using a grinding stone of a large grain size. However, the present invention is not limited thereto. Convexly and concavely shaped portion 12 may be formed, for example, by grinding second main surface 2B made rough by using a grinding stone of a smaller grain size after the aforementioned lapping. In this case, variations in thickness of semiconductor base member 2 can be reduced as compared with the case of forming convexly and concavely shaped portion 12 only by lapping. Particularly when thin semiconductor base member 2 is used, the deflective strength of semiconductor base member 2 itself decreases. However, by grinding or polishing with a grinding stone of a small grain size, the deflective strength of semiconductor base member 2 itself can be increased.

In the method for manufacturing sensor element 1 according to the first embodiment, convexly and concavely shaped portion 12 is formed by grinding second main surface 2B. However, the present invention is not limited thereto. Convexly and concavely shaped portion 12 may be formed, for example, by ion milling. Specifically, convexly and concavely shaped portion 12 may be formed, for example, by sputtering entire second main surface 2B of semiconductor base member 2 using argon (Ar) plasma. With this configuration as well, an effect similar to that of the method for manufacturing sensor element 1 according to the first embodiment described above can be obtained. In addition, convexly and concavely shaped portion 12 can be formed without using the abrasive (abrasive grains) having a high environmental impact.

Convexly and concavely shaped portion 12 may also be formed, for example, by sandblasting. With this configuration as well, an effect similar to that of the method for manufacturing sensor element 1 according to the first embodiment described above can be obtained, and convexly and concavely shaped portion 12 can be formed without using the abrasive (abrasive grains) having a high environmental impact.

In sensor element 1 according to the first embodiment, convexly and concavely shaped portion 12 is formed over entire second main surface 2B. However, the present invention is not limited thereto. Convexly and concavely shaped portion 12 may be formed, for example, only on second main surface 2B located on a region where semiconductor base member 2 is to be left, other than the regions where cavity structures 9 and 10 are to be formed. With this configuration as well, an effect similar to that of the method for manufacturing sensor element 1 according to the first embodiment can be obtained.

In sensor element 1 according to the first embodiment, lower protection film 3 is formed on convexly and concavely shaped portion 12. However, lower protection film 3 may be removed after the step (S50) of forming cavity structures 9 and 10. Specifically, by immersing the second main surface 2B side of semiconductor base member 2 in buffered hydrofluoric acid (BHF) or the like, lower protection film 3 may be removed by wet etching. As a result, sensor element 1 having cavity structures 9 and 10 and having exposed convexly and concavely shaped portion 12 can be formed.

### Second Embodiment

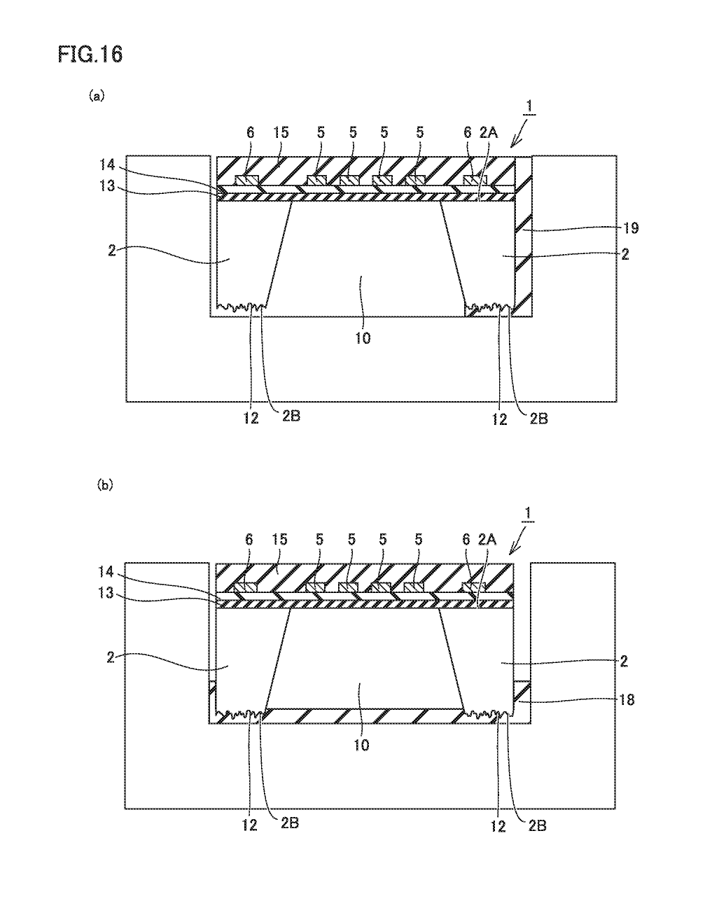

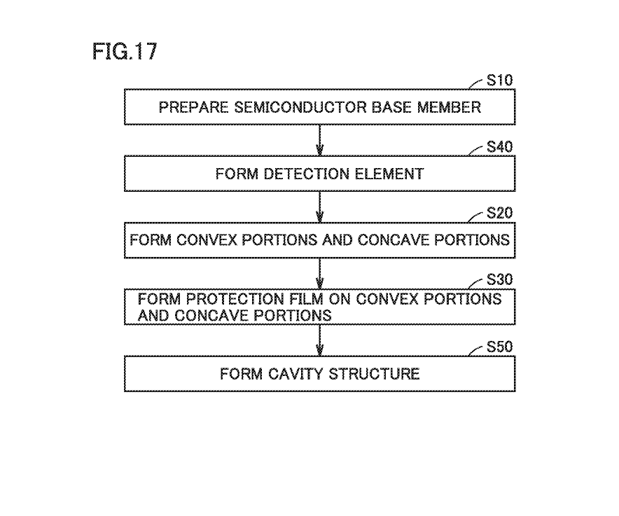

Next, a detection device 100 according to a second embodiment will be described with reference to FIGS. 15 and 16. Detection device 100 is configured by fixing, to a support member 20, sensor element 1 according to the first embodiment in which lower protection film 3 is removed to expose convexly and concavely shaped portion 12. Support member 20 has an incorporation portion in which sensor element 1 is arranged and incorporated, and this incorporation portion is provided to be capable of housing sensor element 1. Support member 20 is disposed on a conduit through which the fluid to be measured flows. Sensor element 1 is fixed in the incorporation portion of support member 20. Sensor element 1 and support member 20 are fixed, for example, by bonding, with an adhesive 18, support member 20 and convexly and concavely shaped portion 12 located below a region where electrode pads 8 are formed. A bottom flow inhibitor 19 is filled into a region which is located upstream of cavity structures 9 and 10 in flowing direction A of the fluid to be measured, and in which sensor element 1 and support member 20 face each other.

Although a material forming adhesive 18 can be an arbitrary adhesive that can bond sensor element 1 and support member 20, the material forming adhesive 18 is preferably a thermosetting adhesive. Although a material forming bottom flow inhibitor 19 can be an arbitrary material that can fill a region between sensor element 1 and support member 20, the material forming bottom flow inhibitor 19 is, for example, an ordinary temperature curable adhesive.

A method for manufacturing detection device 100 according to the second embodiment includes: the step (S100) of preparing sensor element 1 by using the method for manufacturing the sensor element according to the first embodiment; the step (S110) of preparing support member 20 provided such that sensor element 1 is attachable thereto; and the step (S120) of bonding sensor element 1 and support member 20 by using convexly and concavely shaped portion 12 as a bonding surface.

In the step (S100) of preparing sensor element 1, sensor element 1 according to the first embodiment is prepared by using the method for manufacturing the sensor element according to the first embodiment described above. Furthermore, lower protection film 3 of obtained sensor element 1 is removed to prepare sensor element 1 in which convexly and concavely shaped portion 12 is exposed. Then, in the step (S110) of preparing support member 20, above-described support member 20 may be prepared by using an arbitrary method.

In the step (S120) of bonding sensor element 1 and support member 20, each of adhesive 18 and bottom flow inhibitor 19 is first applied preliminarily to a prescribed region in the incorporation portion of support member 20. Specifically, in the incorporation portion of support member 20, adhesive 18 is applied to a region located below electrode pads 8 when sensor element 1 is fixed, and bottom flow inhibitor 19 is applied to a region located upstream of cavity structures 9 and 10 in flowing direction A of the fluid to be measured when sensor element 1 is fixed. At this time, an amount of applied bottom flow inhibitor 19 is adjusted to prevent bottom flow inhibitor 19 from being pressed by sensor element 1 and overflowing to the first main surface 2A side of sensor element 1 and from overflowing into cavity structures 9 and 10 on the second main surface 2B side when sensor element 1 is incorporated into the incorporation portion of support member 20.

Next, sensor element 1 is incorporated into the incorporation portion of support member 20. At this time, sensor element 1 is pressed against support member 20. At this time, adhesive 18 and bottom flow inhibitor 19 preliminarily applied to the region in the incorporation portion of support member 20 are pressed by convexly and concavely shaped portion 12 of sensor element 1 and spread out to a region located between sensor element 1 and support member 20. As a result, bottom flow inhibitor 19 moves through a gap formed between sensor element 1 and support member 20 and is filled to the same height as that of first main surface 2A of sensor element 1. In this way, detection device 100 according to the second embodiment can be obtained.

Next, a function and effect of detection device 100 according to the second embodiment and the method for manufacturing the same will be described. In detection device 100, sensor element 1 according to the first embodiment is used as a flow rate detection element. Cavity structures 9 and 10 of sensor element 1 are formed accurately with respect to a design dimension. Therefore, even when sensor element 1 is pressed against support member 20 in the step (S120) of bonding sensor element 1 and support member 20, sensor element 1 is not broken. As a result, detection device 100 can have high yield.

Furthermore, convexly and concavely shaped portion 12 is formed on second main surface 2B. Therefore, when sensor element 1 is incorporated into the incorporation portion of support member 20, a gap having a prescribed volume is formed between second main surface 2B and support member 20. Therefore, adhesive 18 and bottom flow inhibitor 19 enter this gap and a contact area between second main surface 2B and adhesive 18 and bottom flow inhibitor 19 is increased, and thus, adhesion between sensor element 1 and support member 20 can be enhanced by the anchor effect. In addition, overflow of adhesive 18 and bottom flow inhibitor 19 onto first main surface 2A and into cavity structures 9 and 10 can be suppressed.

In detection device 100 according to the second embodiment, lower protection film 3 formed on convexly and concavely shaped portion 12 in the method for manufacturing sensor element 1 according to the first embodiment is removed. However, the present invention is not limited thereto. For example, sensor element 1 may be bonded to support member 20, with lower protection film 3 being formed. With this configuration as well, an effect similar to that of detection device 100 according to the second embodiment can be obtained.

In addition, sensor element 1 according to the first embodiment is formed as a flow rate detection element and detection device 100 according to the second embodiment is formed as a flow rate detection device. However, the present invention is not limited thereto. Sensor element 1 can be an arbitrary sensor element having cavity structures 9 and 10, and may be, for example, a pressure sensor or an ultrasonic sensor. Namely, detection device 100 can be an arbitrary detection device including the sensor element having cavity structures 9 and 10, and may be, for example, a pressure detection device or an ultrasonic detection device.

In addition, in the method for manufacturing the sensor element according to the first embodiment, the step (S40) of forming detection elements 4 and 5 is performed after the step (S20) of forming convexly and concavely shaped portion 12. However, the present invention is not limited thereto. Referring to FIG. 17, the step (S40) of forming detection elements 4 and 5 may be performed before the step (S20) of forming convexly and concavely shaped portion 12. Specifically, similarly to the method for manufacturing the sensor element according to the first embodiment, the step (S10) of preparing semiconductor base member 2 may be first performed, and thereafter, the step (S40) of forming detection elements 4 and 5 on first main surface 2A of prepared semiconductor base member 2 may be performed. Thereafter, the step (S20) of forming convexly and concavely shaped portion 12 on second main surface 2B of semiconductor base member 2, the step (S30) of forming the protection film (lower protection film 3) on convexly and concavely shaped portion 12, and the step (S50) of forming cavity structures 9 and 10 by forming the opening pattern in the protection film (lower protection film 3) and etching semiconductor base member 2 exposed in the opening pattern by using lower protection film 3 as a mask may be performed. With this configuration as well, sensor element 1 according to the first embodiment can be manufactured. Furthermore, semiconductor base member 2 is thick and difficult to be broken in the step (S40), and thus, a rate of defects caused by breakage and the like can be reduced. In addition, the scratch formed on second main surface 2B in the step (S40) can be removed during grinding in the step (S20).

### Third Embodiment

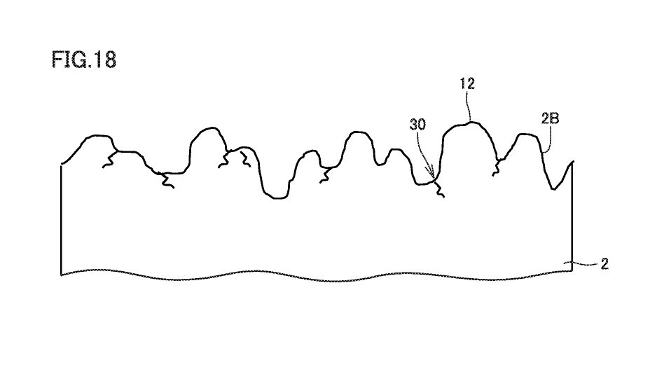

Next, sensor element 1 according to a third embodiment will be described. When convexly and concavely shaped portion 12 is formed by using a method such as grinding in the step (S20) of forming convexly and concavely shaped portion 12 in the method for manufacturing sensor element 1 according to the first embodiment, a cracked layer 30 shown in FIG. 18 may be formed in second main surface 2B of sensor element 1. When a thickness of semiconductor base member 2 exceeds 100 μm, there is a low possibility that insufficient strength of semiconductor base member 2 becomes a major problem even if cracked layer 30 is formed. However, when the thickness of semiconductor base member 2 is small, i.e., not greater than 100 μm, formation of cracked layer 30 may lead to insufficient strength of semiconductor base member 2. Although sensor element 1 according to the third embodiment basically includes a configuration similar to that of sensor element 1 according to the first embodiment, sensor element 1 according to the third embodiment is different from sensor element 1 according to the first embodiment in that cracked layer 30 is not formed at second main surface 10B. Therefore, sensor element 1 according to the third embodiment can produce an effect similar to that of sensor element 1 according to the first embodiment. In addition, even when the thickness of semiconductor base member 2 is not greater than 100 μm, sensor element 1 according to the third embodiment has a sufficient strength and has a high pressing resistance.

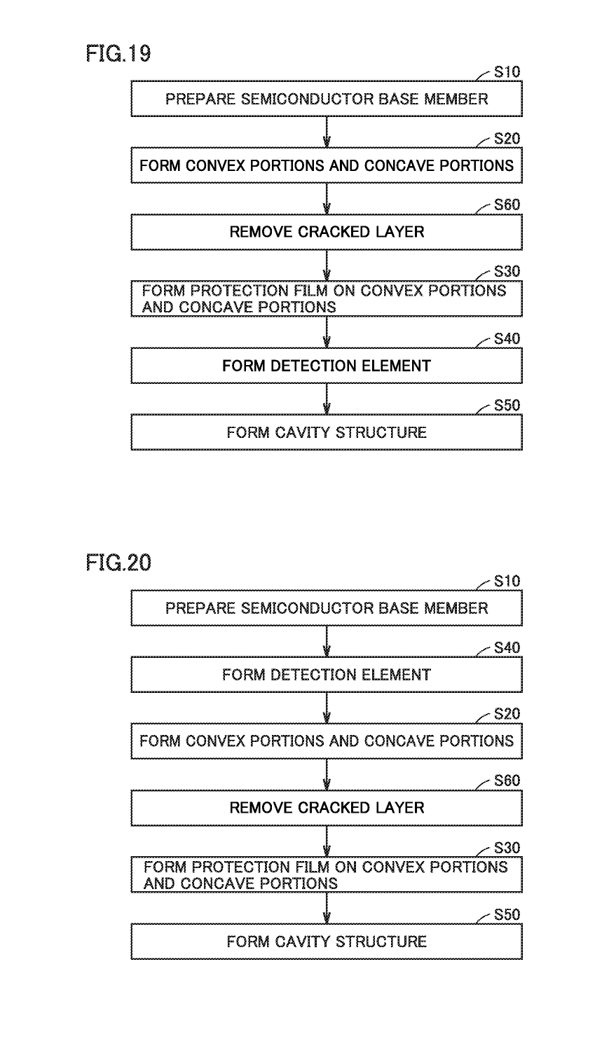

Next, a method for manufacturing sensor element 1 according to the third embodiment will be described with reference to FIG. 19. Although the method for manufacturing sensor element 1 according to the third embodiment basically includes a configuration similar to that of the method for manufacturing sensor element 1 according to the first embodiment shown in FIG. 4, the method for manufacturing sensor element 1 according to the third embodiment is different from the method for manufacturing sensor element 1 according to the first embodiment in terms of including the step (S60) of removing cracked layer 30 formed in second main surface 2B in the step (S20) of forming convexly and concavely shaped portion 12.

The step (S60) of removing cracked layer 30 is performed after the step (S20) of forming convexly and concavely shaped portion 12 and before the step (S30) of forming the protection film. In this step (S60), second main surface 2B of semiconductor base member 2 is subjected to wet etching. An etching solution is, for example, an aqueous solution of TMAH, KOH or the like. Second main surface 2B of semiconductor base member 2 is immersed in a bath containing the heated etching solution. In this way, cracked layer 30 formed in second main surface 2B can be removed. Namely, in accordance with the method for manufacturing the sensor element according to the third embodiment, an effect similar to that of the method for manufacturing sensor element 1 according to the first embodiment can be obtained. In addition, cracked layer 30 can be easily removed and sensor element 1 having a high resistance during pressing can be manufactured.

Referring to FIG. 20, the method for manufacturing sensor element 1 according to the third embodiment may basically include a configuration similar to that of a modification of the method for manufacturing sensor element 1 according to the first embodiment shown in FIG. 17, and the method for manufacturing sensor element 1 according to the third embodiment may be different from the modification in terms of including the step (S60) of removing cracked layer 30 formed in second main surface 2B in the step (S20) of forming convexly and concavely shaped portion 12. Specifically, in the method for manufacturing sensor element 1 in which the step (S20) of forming convexly and concavely shaped portion 12 on second main surface 2B of semiconductor base member 2 and the step (S30) of forming the protection film (lower protection film 3) on convexly and concavely shaped portion 12 are performed after the step (S40) of forming detection elements 4 and 5 on first main surface 2A of semiconductor base member 2, the step (S60) of removing cracked layer 30 is performed after the above-described step (S20) and before the above-described step (S30). With this configuration as well, an effect similar to that of the method for manufacturing sensor element 1 according to the third embodiment can be obtained.

While the embodiments of the present invention have been described above, various modifications may also be made to the above-described embodiments. In addition, the scope of the present invention is not limited to the above-described embodiments. The scope of the present invention is defined by the terms of the claims, and is intended to include any modifications within the scope and meaning equivalent to the terms of the claims.

### INDUSTRIAL APPLICABILITY

The present invention is particularly advantageously applied to a sensor element having a cavity structure.

### REFERENCE SIGNS LIST

1 sensor element; 2 semiconductor base member; 2A first main surface; 2B second main surface; 3 lower protection film; 3B lower surface; 4 intake air temperature detector (detection element); 5 heat generator (detection element); 6, 7 wiring pattern; 8 electrode pad; 9, 10 cavity structure; 12 convexly and concavely shaped portion; 13 upper protection film; 14 support film; 15 surface protection film; 16 dicing line; 18 adhesive; 19 bottom flow inhibitor; 20 support member; 100 detection device.

1. A sensor element, comprising:
a semiconductor base member having a first main surface and a second main surface located opposite to the first main surface, and having a cavity structure formed on the second main surface side; and
a detection element formed on the first main surface side in a region where the cavity structure is formed,
the second main surface of the semiconductor base member including a convexly and concavely shaped portion, and
a tip of a convex portion of the convexly and concavely shaped portion having a curved shape.

2. The sensor element according to claim 1, further comprising
a protection film formed on the convexly and concavely shaped portion, wherein
a ten-point average roughness of the convexly and concavely shaped portion is equal to or greater than a film thickness of the protection film.

3. A detection device, comprising the sensor element as recited in claim 1.

4. A method for manufacturing a sensor element, comprising the steps of:
preparing a semiconductor substrate having a first main surface and a second main surface located opposite to the first main surface;
forming a convexly and concavely shaped portion on the second main surface of the semiconductor substrate;
forming a protection film on the convexly and concavely shaped portion;
forming a cavity structure by forming an opening pattern in the protection film and etching the semiconductor substrate exposed in the opening pattern by using the protection film as a mask; and
forming a detection element on the first main surface side in a region where the cavity structure is formed,
in the step of forming the convexly and concavely shaped portion, the convexly and concavely shaped portion being formed such that a tip of a convex portion of the convexly and concavely shaped portion has a curved shape.

5. The method for manufacturing a sensor element according to claim 4, wherein
in the step of forming the convexly and concavely shaped portion and the step of forming the protection film, the convexly and concavely shaped portion and the protection film are formed such that a ten-point average roughness of the convexly and concavely shaped portion is equal to or greater than a film thickness of the protection film.

6. The method for manufacturing a sensor element according to claim 4, wherein
in the step of forming the convexly and concavely shaped portion, the convexly and concavely shaped portion is formed by grinding.

7. The method for manufacturing a sensor element according to claim 4, wherein
in the step of forming the convexly and concavely shaped portion, the convexly and concavely shaped portion is formed by ion milling.

8. (canceled)

9. The method for manufacturing a sensor element according to claim 4, wherein
in the step of forming the protection film, the protection film is formed by thermally oxidizing the second main surface.

10. The method for manufacturing a sensor element according to claim 4, wherein
the step of forming the detection element is performed before the step of forming the convexly and concavely shaped portion.

11. The method for manufacturing a sensor element according to claim 4, wherein
the step of forming the detection element is performed after the step of forming the convexly and concavely shaped portion.

12. The method for manufacturing a sensor element according to claim 4, wherein
in the step of forming the convexly and concavely shaped portion, a cracked layer is formed in the second main surface,
the method for manufacturing a sensor element further comprising the step of removing the cracked layer.

13. A method for manufacturing a detection device, comprising the steps of:
preparing the sensor element by using the method for manufacturing the sensor element as recited in claim 4;
preparing a support member provided such that the sensor element is attachable thereto; and
bonding the sensor element and the support member by using the convexly and concavely shaped portion as a bonding surface.

14. A detection device, comprising the sensor element as recited in claim 2.

15. The method for manufacturing a sensor element according to claim 5, wherein
in the step of forming the convexly and concavely shaped portion, the convexly and concavely shaped portion is formed by grinding.

16. The method for manufacturing a sensor element according to claim 5, wherein
in the step of forming the convexly and concavely shaped portion, the convexly and concavely shaped portion is formed by ion milling.

17. The method for manufacturing a sensor element according to claim 5, wherein
in the step of forming the protection film, the protection film is formed by thermally oxidizing the second main surface.

18. The method for manufacturing a sensor element according to claim 5, wherein
the step of forming the detection element is performed before the step of forming the convexly and concavely shaped portion.

19. The method for manufacturing a sensor element according to claim 5, wherein
the step of forming the detection element is performed after the step of forming the convexly and concavely shaped portion.

20. The method for manufacturing a sensor element according to claim 5, wherein
in the step of forming the convexly and concavely shaped portion, a cracked layer is formed in the second main surface,
the method for manufacturing a sensor element further comprising the step of removing the cracked layer.

21. A method for manufacturing a detection device, comprising the steps of:
preparing the sensor element by using the method for manufacturing the sensor element as recited in claim 5;
preparing a support member provided such that the sensor element is attachable thereto; and
bonding the sensor element and the support member by using the convexly and concavely shaped portion as a bonding surface.
